(19) United States
(12) Patent Application Publication
(10) Pub. No.: US 2015/0221791 A1
(43) Pub. Date: Aug. 6, 2015

(54) PHOTOELECTRIC CONVERSION ELEMENT

(71) Applicant: SHARP KABUSHIKI KAISHA, Osaka-shi, Osaka (JP)

(72) Inventors: Masatomi Harada, Osaka-shi (JP); Kenji Kimoto, Osaka-shi (JP); Naoki Koide, Osaka-shi (JP); Yoshitaka Yamamoto, Osaka-shi (JP); Kyotaro Nakamura, Osaka-shi (JP)

(21) Appl. No.: 14/427,054

(22) PCT Filed: Sep. 19, 2013
(86) PCT No.: PCT/JP2013/075262

§ 371 Date: Mar. 10, 2015

(30) Foreign Application Priority Data
Sep. 25, 2012 (JP) 2012-210904

(51) Int. Cl. H01L 31/0224

(52) U.S. Cl. CPC H01L 31/022441

(57) ABSTRACT

Provided is a photoelectric conversion element which includes a first conductive semiconductor substrate of a first conductivity type, a first semiconductor film of the first conductivity type disposed on one front surface of the semiconductor substrate, a second semiconductor film of a second conductivity type disposed on the front surface to be independent from the first semiconductor film, and a dielectric film disposed between the semiconductor substrate and the first semiconductor film and/or between the semiconductor substrate and the second semiconductor film, in which an intermetallic compound layer is formed on the first semiconductor film and on the second semiconductor film.

### TECHNICAL FIELD

The present invention relates to a photoelectric conversion element and a manufacturing method of the photoelectric conversion element.

### BACKGROUND ART

Recently, expectations for a solar cell capable of directly converting solar energy into electric energy have increased rapidly as an energy source of the next generation, in particular, from a viewpoint of global environmental problems. As the solar cell, various solar cells such as a solar cell using a compound semiconductor or an organic material are included, and currently, a solar cell using silicon crystal is mainly being used.

Currently, a solar cell which has been manufactured and sold most commonly is a solar cell having a structure where electrodes are respectively formed on a light receiving surface on a side on which solar light is incident and on a back surface on an opposite side of the light receiving surface.

However, when the electrode is formed on the light receiving surface, the amount of solar light to be incident is decreased by the area of the electrode due to reflection and absorption of the solar light in the electrode. Therefore, for example, a solar cell in which the electrode is formed only on the back surface as illustrated in Japanese Unexamined Patent Application Publication No. 2010-80887 (PTL 1) has been developed.

### CITATION LIST

### Patent Literature

PTL 1: Japanese Unexamined Patent Application Publication No. 2010-80887

### SUMMARY OF INVENTION

### Technical Problem

Hereinafter, an example of a manufacturing method of the solar cell in which the electrode is formed only on the back surface will be described with reference to schematic cross-sectional views of FIG. 28 to FIG. 44. First, as illustrated in FIG. 28, an a-Si (i/p) layer 902 in which an i-type amorphous silicon film and a p-type amorphous silicon film are laminated in this order is formed on a back surface of a c-Si (n) substrate 901 formed of n-type single crystal silicon in which a textured structure (not illustrated) is formed on a light receiving surface.

Next, as illustrated in FIG. 29, an a-Si (i/n) layer 903 in which an i-type amorphous silicon film and an n-type amorphous silicon film are laminated in this order is formed on the light receiving surface of the c-Si (n) substrate 901.

Next, as illustrated in FIG. 30, a photoresist film 904 is formed on a part of a back surface of the a-Si (i/p) layer 902. Here, the entire back surface of the a-Si (i/p) layer 902 is coated with photoresist, then the photoresist is patterned through a photolithography technology and an etching technology, and thus the photoresist film 904 is formed.

Next, as illustrated in FIG. 31, a part of the a-Si (i/p) layer 902 is etched by using the photoresist film 904 as a mask, and thus the back surface of the c-Si (n) substrate 901 is exposed.

Next, as illustrated in FIG. 32, the photoresist film 904 is removed, then as illustrated in FIG. 33, a-Si (i/n) layer 905 in which an i-type amorphous silicon film and an n-type amorphous silicon film are laminated in this order is formed to cover the back surface of the a-Si (i/p) layer 902 which is exposed by removing the photoresist film 904 and the back surface of the c-Si (n) substrate 901 which is exposed by the etching.

Next, as illustrated in FIG. 34, a photoresist film 906 is formed on a part of a back surface of the a-Si (i/n) layer 905. Here, the entire back surface of the a-Si (i/n) layer 905 is coated with photoresist, then the photoresist is patterned by a photolithography technology and an etching technology, and thus the photoresist film 906 is formed.

Next, as illustrated in FIG. 35, a part of the a-Si (i/n) layer 905 is etched by using the photoresist film 906 as a mask, and thus the back surface of the a-Si (i/p) layer 902 is exposed.

Next, as illustrated in FIG. 36, the photoresist film 906 is removed, then as illustrated in FIG. 37, a transparent conductive oxide film 907 is formed to cover the back surface of the a-Si (i/n) layer 905 which is exposed by removing the photoresist film 906 and the back surface of the a-Si (i/p) layer 902 which is exposed by the etching.

Next, as illustrated in FIG. 38, a photoresist film 908 is formed on a part of a back surface of the transparent conductive oxide film 907. Here, the entire back surface of the transparent conductive oxide film 907 is coated with photoresist, then the photoresist is patterned through a photolithography technology and an etching technology, and thus the photoresist film 908 is formed.

Next, as illustrated in FIG. 39, a part of the transparent conductive oxide film 907 is etched by using the photoresist film 908 as a mask, and thus the back surface of the a-Si (i/p) layer 902 and the a-Si (i/n) layer 905 is exposed.

Next, as illustrated in FIG. 40, the photoresist film 908 is removed, then as illustrated in FIG. 41, a photoresist film 909 is formed to cover the exposed back surface of the a-Si (i/p) layer 902 and the a-Si (i/n) layer 905 and a part of the back surface of the transparent conductive oxide film 907. Here, the entire exposed back surface of the a-Si (i/p) layer 902 and the a-Si (i/n) layer 905 and the entire back surface of the transparent conductive oxide film 907 are coated with photoresist, then the photoresist is patterned through a photolithography technology and an etching technology, and thus the photoresist film 909 is formed.

Next, as illustrated in FIG. 42, a back surface electrode layer 910 is formed on the entire back surfaces of the transparent conductive oxide film 907 and the photoresist film 909.

Next, as illustrated in FIG. 43, the back surface electrode layer 910 remains only in a part of the front surface of the transparent conductive oxide film 907, and the photoresist film 909 and the back surface electrode layer 910 are removed by liftoff.

Next, as illustrated in FIG. 44, an antireflective film 911 is formed on a front surface of the a-Si (i/n) layer 903.

However, in the manufacturing method of a solar cell described above, it is necessary to apply the photoresist, and to perform a complicated patterning process with respect to the photoresist by using the photolithography technology and the etching technology, and thus a manufacturing process of the solar cell in which the electrode is formed only on the back surface is extremely complicated. In addition, conversion efficiency of the solar cell in which the electrode is formed only on the back surface is also required to be improved.

The present invention is made in consideration of the circumstances described above, and is to provide a photoelectric conversion element which is able to improve power generation efficiency and is able to be manufactured by a simple manufacturing process.

### Solution to Problem

A photoelectric conversion element of the present invention includes both p-type and n-type semiconductor films on a back surface of a semiconductor substrate, and an intermetallic compound layer is formed on the semiconductor film. Then, the intermetallic compound layer formed on the p-type semiconductor film and the intermetallic compound layer formed on the n-type semiconductor film are separated from each other by a space.

That is, the photoelectric conversion element of the present invention includes a semiconductor substrate of a first conductivity type, a first semiconductor film of the first conductivity type disposed on one surface of the semiconductor substrate, a second semiconductor film of a second conductivity type disposed on the one surface to be independent from the first semiconductor film, and a dielectric film disposed between the semiconductor substrate and the first semiconductor film and/or between the semiconductor substrate and the second semiconductor film, and an intermetallic compound layer is formed on the first semiconductor film and on the second semiconductor film.

Here, it is preferable that a groove is formed in the one surface of the semiconductor substrate, and the second semiconductor film is disposed on a bottom surface of the groove.

Further, it is preferable that at least a part of a side wall of the groove is covered with an insulating film.

In addition, the first semiconductor film and the second semiconductor film may be disposed on the one surface of the semiconductor substrate to be separated from each other, and an insulating film may be disposed between the first semiconductor film and the second semiconductor film.

In addition, it is preferable that the intermetallic compound layer is a metal silicide layer and/or a metal germanide layer. Here, it is preferable that the metal silicide layer is a compound layer formed of silicon and at least one metal selected from a group consisting of nickel, cobalt, and titanium, and it is preferable that the metal germanide is a compound layer formed of germanium and at least one metal selected from a group consisting of nickel, cobalt, and titanium.

In addition, it is preferable that the insulating film is a thermally oxidized silicon film and/or a silicon nitride film, and when the insulating film is a silicon nitride film, it is preferable that the silicon nitride film is formed by using a plasma CVD method.

In addition, the present invention relates to a manufacturing method of the photoelectric conversion element, and the manufacturing method includes a step of forming a metal layer on the entire surface on one surface side of a semiconductor substrate of a first conductivity type including a first semiconductor film of the first conductivity type and a second semiconductor film of a second conductivity type which are exposed on the one surface, and a step of forming an intermetallic compound layer by allowing the first semiconductor film and the second semiconductor film to react with the metal layer due to a heat treatment.

Here, it is preferable that the step of forming the intermetallic compound layer is a step of forming a metal silicide layer, and it is preferable that the step of forming the intermetallic compound layer further includes a step of removing an unreacted metal layer after the step of forming the metal silicide layer.

In addition, the step of forming the intermetallic compound layer may be a step of forming a metal germanide layer, and the step of forming the intermetallic compound layer may further include a step of removing an unreacted metal layer after the step of forming the metal germanide layer.

Further, it is preferable that the metal layer is a layer formed of at least one metal selected from a group consisting of nickel, cobalt, and titanium.

Furthermore, herein, “first conductivity type” indicates “n-type” or “p-type”, and “second conductivity type” indicates “p-type” or “n-type” different from the first conductivity type.

### Advantageous Effects of Invention

According to the present invention, it is possible to provide a photoelectric conversion element which is able to improve power generation efficiency and is able to be manufactured by a simple manufacturing process.

### BRIEF DESCRIPTION OF DRAWINGS

FIG. 1 is a schematic cross-sectional view of a photoelectric conversion element of a first embodiment.

FIG. 2 is a schematic cross-sectional view of the photoelectric conversion element of a second embodiment.

FIG. 3 is a schematic cross-sectional view illustrating a part of a manufacturing process which is an example of a manufacturing method of the photoelectric conversion element of the first embodiment.

FIG. 4 is a schematic cross-sectional view illustrating a part of the manufacturing process which is an example of the manufacturing method of the photoelectric conversion element of the first embodiment.

FIG. 5 is a schematic cross-sectional view illustrating a part of the manufacturing process which is an example of the manufacturing method of the photoelectric conversion element of the first embodiment.

FIG. 6 is a schematic cross-sectional view illustrating a part of the manufacturing process which is an example of the manufacturing method of the photoelectric conversion element of the first embodiment.

FIG. 7 is a schematic cross-sectional view illustrating a part of the manufacturing process which is an example of the manufacturing method of the photoelectric conversion element of the first embodiment.

FIG. 8 is a schematic cross-sectional view illustrating a part of the manufacturing process which is an example of the manufacturing method of the photoelectric conversion element of the first embodiment.

FIG. 9 is a schematic cross-sectional view illustrating a part of the manufacturing process which is an example of the manufacturing method of the photoelectric conversion element of the first embodiment.

FIG. 10 is a schematic cross-sectional view illustrating a part of the manufacturing process which is an example of the manufacturing method of the photoelectric conversion element of the first embodiment.

FIG. 11 is a schematic cross-sectional view illustrating a part of the manufacturing process which is an example of the manufacturing method of the photoelectric conversion element of the first embodiment.

FIG. 12 is a schematic cross-sectional view illustrating a part of the manufacturing process which is an example of the manufacturing method of the photoelectric conversion element of the first embodiment.

FIG. 13 is a schematic cross-sectional view illustrating a part of the manufacturing process which is an example of the manufacturing method of the photoelectric conversion element of the first embodiment.

FIG. 14 is a schematic cross-sectional view illustrating a part of the manufacturing process which is an example of the manufacturing method of the photoelectric conversion element of the first embodiment.

FIG. 15 is a schematic cross-sectional view illustrating a part of the manufacturing process which is an example of the manufacturing method of the photoelectric conversion element of the first embodiment.

FIG. 16 is a schematic cross-sectional view illustrating a part of the manufacturing process which is an example of the manufacturing method of the photoelectric conversion element of the first embodiment.

FIG. 17 is a schematic cross-sectional view illustrating a part of the manufacturing process which is an example of the manufacturing method of the photoelectric conversion element of the first embodiment.

FIG. 18 is a schematic cross-sectional view illustrating a part of a manufacturing process which is an example of a manufacturing method of the photoelectric conversion element of the second embodiment.

FIG. 19 is a schematic cross-sectional view illustrating a part of the manufacturing process which is an example of the manufacturing method of the photoelectric conversion element of the second embodiment.

FIG. 20 is a schematic cross-sectional view illustrating a part of the manufacturing process which is an example of the manufacturing method of the photoelectric conversion element of the second embodiment.

FIG. 21 is a schematic cross-sectional view illustrating a part of the manufacturing process which is an example of the manufacturing method of the photoelectric conversion element of the second embodiment.

FIG. 22 is a schematic cross-sectional view illustrating a part of the manufacturing process which is an example of the manufacturing method of the photoelectric conversion element of the second embodiment.

FIG. 23 is a schematic cross-sectional view illustrating a part of the manufacturing process which is an example of the manufacturing method of the photoelectric conversion element of the second embodiment.

FIG. 24 is a schematic cross-sectional view illustrating a part of the manufacturing process which is an example of the manufacturing method of the photoelectric conversion element of the second embodiment.

FIG. 25 is a schematic cross-sectional view illustrating a part of the manufacturing process which is an example of the manufacturing method of the photoelectric conversion element of the second embodiment.

FIG. 26 is a schematic cross-sectional view illustrating a part of the manufacturing process which is an example of the manufacturing method of the photoelectric conversion element of the second embodiment.

FIG. 27 is a schematic cross-sectional view illustrating a part of the manufacturing process which is an example of the manufacturing method of the photoelectric conversion element of the second embodiment.

FIG. 28 is a schematic cross-sectional view illustrating a part of a manufacturing process which is an example of a manufacturing method of a solar cell in which an electrode is formed only on a back surface.

FIG. 29 is a schematic cross-sectional view illustrating a part of the manufacturing process which is an example of the manufacturing method of the solar cell in which the electrode is formed only on the back surface.

FIG. 30 is a schematic cross-sectional view illustrating a part of the manufacturing process which is an example of the manufacturing method of the solar cell in which the electrode is formed only on the back surface.

FIG. 31 is a schematic cross-sectional view illustrating a part of the manufacturing process which is an example of the manufacturing method of the solar cell in which the electrode is formed only on the back surface.

FIG. 32 is a schematic cross-sectional view illustrating a part of the manufacturing process which is an example of the manufacturing method of the solar cell in which the electrode is formed only on the back surface.

FIG. 33 is a schematic cross-sectional view illustrating a part of the manufacturing process which is an example of the manufacturing method of the solar cell in which the electrode is formed only on the back surface.

FIG. 34 is a schematic cross-sectional view illustrating a part of the manufacturing process which is an example of the manufacturing method of the solar cell in which the electrode is formed only on the back surface.

FIG. 35 is a schematic cross-sectional view illustrating a part of the manufacturing process which is an example of the manufacturing method of the solar cell in which the electrode is formed only on the back surface.

FIG. 36 is a schematic cross-sectional view illustrating a part of the manufacturing process which is an example of the manufacturing method of the solar cell in which the electrode is formed only on the back surface.

FIG. 37 is a schematic cross-sectional view illustrating a part of the manufacturing process which is an example of the manufacturing method of the solar cell in which the electrode is formed only on the back surface.

FIG. 38 is a schematic cross-sectional view illustrating a part of the manufacturing process which is an example of the manufacturing method of the solar cell in which the electrode is formed only on the back surface.

FIG. 39 is a schematic cross-sectional view illustrating a part of the manufacturing process which is an example of the manufacturing method of the solar cell in which the electrode is formed only on the back surface.

FIG. 40 is a schematic cross-sectional view illustrating a part of the manufacturing process which is an example of the manufacturing method of the solar cell in which the electrode is formed only on the back surface.

FIG. 41 is a schematic cross-sectional view illustrating a part of the manufacturing process which is an example of the manufacturing method of the solar cell in which the electrode is formed only on the back surface.

FIG. 42 is a schematic cross-sectional view illustrating a part of the manufacturing process which is an example of the manufacturing method of the solar cell in which the electrode is formed only on the back surface.

FIG. 43 is a schematic cross-sectional view illustrating a part of the manufacturing process which is an example of the manufacturing method of the solar cell in which the electrode is formed only on the back surface.

FIG. 44 is a schematic cross-sectional view illustrating a part of the manufacturing process which is an example of the manufacturing method of the solar cell in which the electrode is formed only on the back surface.

### DESCRIPTION OF EMBODIMENTS

Hereinafter, embodiments of the present invention will be described. Furthermore, in the drawings of the present invention, the same reference numerals indicate the same parts or the corresponding parts.

### Embodiment 1

### [Photoelectric Conversion Element]

### <<Overall Configuration>>

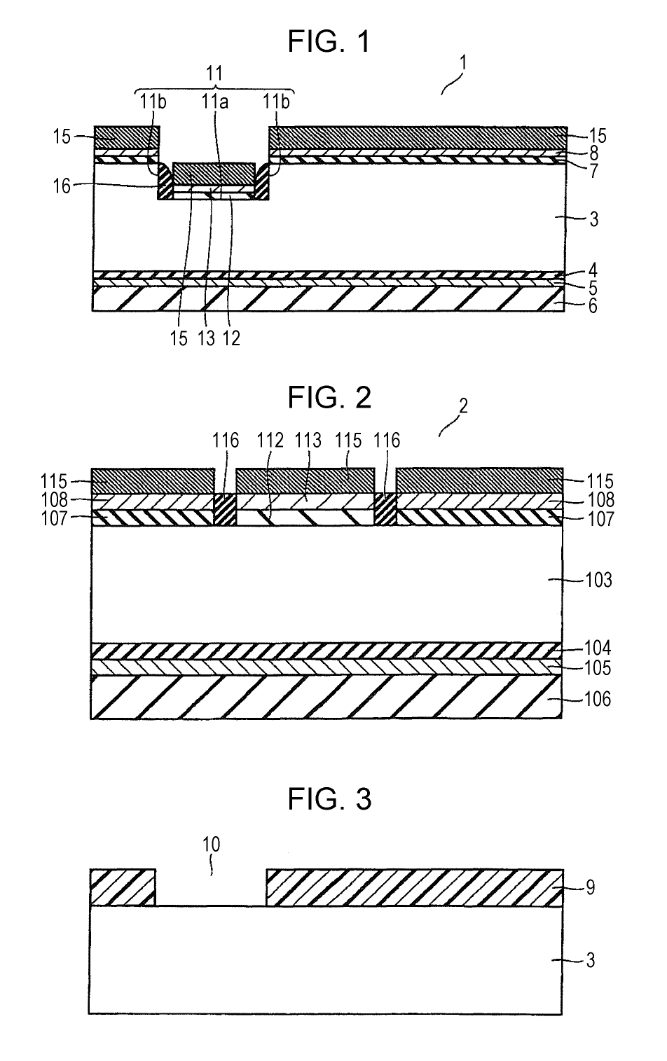

In FIG. 1, a schematic cross-sectional view of a photoelectric conversion element 1 which is a first embodiment of the present invention is illustrated. The photoelectric conversion element 1 which is the first embodiment includes a semiconductor substrate 3 formed of n-type single crystal silicon, and a groove 11 including a bottom surface 11a and side walls 11b on both sides thereof is formed in a part of a back surface which is one surface of the semiconductor substrate 3. Here, the groove 11 extends in a normal direction of the paper in FIG. 1.

A first dielectric film 7 formed of i-type amorphous silicon is disposed on a region of the back surface of the semiconductor substrate 3 other than the groove, and a first semiconductor film 8 formed of n-type amorphous silicon is disposed on the first dielectric film 7. Then, an intermetallic compound layer 15 is formed on the entire back surface of the first semiconductor film 8.

Herein, the “semiconductor film” indicates a film formed of a material which is able to impart conductivity by being doped with impurities. As such a semiconductor film, for example, a silicon film, a germanium film, a gallium arsenide film, and the like are able to be included.

In addition, “i-type” indicates that n-type or p-type impurities are not intentionally doped, and for example, may indicate n-type or p-type of the conductivity type due to inevitable spread of the n-type or the p-type impurities or the like after preparing the photoelectric conversion element.

In addition, in the “amorphous silicon”, amorphous silicon in which a dangling bond of a silicon atom in amorphous silicon hydride or the like is terminated with hydrogen is also included. Similarly, in the “amorphous germanium”, amorphous germanium hydride and the like are included.

A second dielectric film 12 formed of i-type amorphous silicon is disposed on the bottom surface 11a of the groove 11 in the back surface of the semiconductor substrate 3, and a second semiconductor film 13 formed of p-type amorphous silicon is disposed on the second dielectric film 12. Then, an intermetallic compound layer 15 is formed on the entire back surface of the second semiconductor film 13.

An insulating film 16 may be disposed on at least a part of the side wall 11b of the groove 11. In this case, the insulating film 16 is disposed between the second dielectric film 12 and the second semiconductor film 13, and the side walls 11b of the groove 11, and thus the second dielectric film 12 and the second semiconductor film 13 are not in contact with the side wall 11b.

In addition, a third dielectric film 4 formed of i-type amorphous silicon is disposed on the entire light receiving surface (a surface opposite to the back surface) which is the other surface of the semiconductor substrate 3, and a third semiconductor film 5 formed of n-type amorphous silicon is disposed on the entire surface of the third dielectric film 4. Further, an antireflective film 6 is disposed on the entire surface of the third semiconductor film 5.

In the photoelectric conversion element 1 having the structure described above, the first dielectric film 7 is disposed between the back surface of the semiconductor substrate 3 and the back surface of the first semiconductor film 8, and the second dielectric film 12 is disposed between the bottom surface 11a of the groove 11 and the back surface of the second semiconductor film 13.

Therefore, in the photoelectric conversion element 1, a dielectric film is disposed in an entire region between the back surface of the semiconductor substrate 3 and the back surface of the first semiconductor film 8 and between the bottom surface 11a of the groove 11 and the back surface of the second semiconductor film 13.

In addition, in the photoelectric conversion element 1, the intermetallic compound layer 15 is disposed on the entire back surface of the first semiconductor film 8 and on the entire back surface of the second semiconductor film 13, and thus both the first semiconductor film 8 and the second semiconductor film 13 are covered with the intermetallic compound layer 15.

Furthermore, in the photoelectric conversion element 1, a configuration in which the first semiconductor film 8 is of the n-type and the second semiconductor film 13 is of the p-type is exemplified, and even when the first semiconductor film is of the p-type and the second semiconductor film is of the n-type, effects of the present invention are obtained.

In addition, in the photoelectric conversion element 1, a configuration in which the third semiconductor film 5 is disposed on the light receiving surface is exemplified, but the third semiconductor film 5 is not a mandatory component, and even when the third semiconductor film 5 is not included, the effects of the present invention are obtained.

Hereinafter, each component configuring the photoelectric conversion element of this embodiment will be described.

### <<Semiconductor Substrate>>

As the semiconductor substrate 3, a substrate formed of n-type single crystal silicon is able to be typically used, but the material is not limited thereto, and a known material of the related art is able to be widely used. For example, a substrate formed of germanium or a gallium arsenic compound may be used, and not only a single crystal substrate but also a polycrystalline substrate or an amorphous substrate may be used. In addition, for example, a semiconductor substrate or the like in which a textured structure (not illustrated) is formed on the light receiving surface and/or the back surface of the semiconductor substrate 3 in advance may be used.

It is preferable that a thickness of the semiconductor substrate 3 is greater than or equal to 50 μm and less than or equal to 300 μm. By setting the thickness of the semiconductor substrate 3 to be in the range described above, it is possible to prevent a recombination of an electron-hole pair generated in the semiconductor substrate 3, and it is possible to decrease power attenuation. Here, a more preferable range of the thickness of the semiconductor substrate 3 is greater than or equal to 100 μm and less than or equal to 200 μm.

In addition, an impurity concentration of the semiconductor substrate 3 is not particularly limited, and for example, is able to be greater than or equal to 5×10¹⁴ units/cm³ and less than or equal to 2×10¹⁶ units/cm³. As the impurities included in the semiconductor substrate 3, for example, phosphorus, boron, and the like are able to be used.

### <<Groove>>

In addition, a depth D of the groove 11 is not particularly limited, and for example, the depth D is able to be less than or equal to 10 μm, and preferably is able to be less than or equal to 5 μm.

### <<Insulating Film>>

The insulating film 16 is not particularly limited insofar as a film has insulation properties in which insulation resistivity is greater than or equal to 1×10⁴ Ω·cm, and a known insulating film of the related art is able to be used. For example, as the insulating film 16, a silicon oxide film, a silicon nitride film, an aluminum nitride film, an aluminum oxide film, a titanium oxide film, or a combination thereof is able to be included.

Among them, a silicon oxide film formed by thermal oxidization (herein, referred to as a thermally oxidized silicon film) is particularly preferable. The thermally oxidized silicon film is formed at a high temperature of approximately 1000° C., and thus properties thereof are not changed even in a high temperature process of approximately 250° C. of a manufacturing process of a solar cell, and a preferred passivation effect is obtained. Then, more preferably, it is preferable that the thermally oxidized silicon film is subjected to a hydrogen annealing treatment in addition to a thermal oxidation treatment. According to the hydrogen annealing treatment, it is possible to terminate a dangling bond of an interfacial surface between the semiconductor substrate 3 and the thermally oxidized silicon film by hydrogen.

In addition, an aspect in which the insulating film 16 is a silicon nitride film formed by a plasma Chemical Vapor Deposition (CVD) method is one of preferred aspects. When the silicon nitride film is formed by a plasma CVD method, mixed gas formed of silane gas (SiH₄), ammonia gas (NH₃), and the like is used as raw material gas, and hydrogen derived from the raw material gas remains in the insulating film after being formed.

In general, it is not preferable that the hydrogen remains in the insulating film from a viewpoint of impurities. However, the present inventors have newly found that when hydrogen in amorphous silicon is detached due to light degradation or the like in the photoelectric conversion element having the configuration of the present invention, the hydrogen remaining in the insulating film has a function of compensating a hydrogen defect. Therefore, hydrogen is contained in the insulating film, and thus it is possible to have a long life duration of the photoelectric conversion element.

Here, it is preferable that a content of hydrogen in the insulating film is greater than or equal to 0.005 at % and less than or equal to 0.03 at %. When the content exceeds 0.03 at %, in the manufacturing process of a solar cell after forming the insulating film, hydrogen is easily detached, and the insulating film is easily distorted or peeled out, and thus it is not preferable. In addition, when the content is less than 0.005 at %, the effect described above may not be sufficiently obtained, and thus it is not preferable.

Furthermore, the content of hydrogen, for example, is able to be estimated by integrating signals derived from N—H or Si—H using an FT-IR method. In addition, “at %” indicates an “atomic percentage”, that is, a concentration of the number of atoms.

In addition, the insulating film 16 may be a single layer film, or may be a laminated film. That is, it is preferable that the insulating film of the present invention is a thermally oxidized silicon film and/or a silicon nitride film.

Further, it is preferable that the insulating film 16 covers at least a part of the side wall 11b of the groove 11, it is more preferable that a length of the insulating film 16 which is in contact with the side wall 11b of the groove 11 is longer than a summation of thicknesses of the second dielectric film 12 and the second semiconductor film 13, and it is most preferable that the insulating film 16 covers an entire surface of the side wall 11b of the groove 11. In addition, it is preferable that a length of a portion of the insulating film 16 which is in contact with the bottom surface 11a of the groove 11 is greater than or equal to 1 nm and less than or equal to 500 nm in an arbitrary vertical section with respect to the front surface of the semiconductor substrate 3. When the length described above is less than 1 nm, an effect in which a p-type electrode and an n-type electrode are electrically separated from each other may not be sufficiently obtained, and when the length exceed 500 nm, the insulating film 16 may be peeled off at the time of being etched, and thus it is not preferable.

### <<Semiconductor Film>>

In the present invention, it is preferable that the first semiconductor film, the second semiconductor film, and the third semiconductor film are amorphous films, and typically, are films formed of amorphous silicon and/or amorphous germanium exhibiting p-type or n-type conductivity. Hereinafter, each semiconductor film will be described.

### (First Semiconductor Film)

The first semiconductor film 8 is not limited to a film formed of n-type amorphous silicon, and as the first semiconductor film 8, for example, a known n-type amorphous semiconductor film of the related art, or the like may be used. In addition, as the first semiconductor film 8, for example, a film formed of n-type amorphous germanium may be included. A thickness of the first semiconductor film 8 is not particularly limited, and for example, is able to be greater than or equal to 1 nm and less than or equal to 20 nm. Here, as n-type impurities included in the first semiconductor film 8, for example, phosphorus is able to be used, and an n-type impurity concentration of the first semiconductor film 8, for example, is able to be approximately 5×10¹⁹ units/cm³.

### (Second Semiconductor Film)

The second semiconductor film 13 is not limited to a film formed of p-type amorphous silicon, and as the second semiconductor film 13, for example, a known p-type amorphous semiconductor film of the related art, or the like may be used. In addition, as the second semiconductor film 13, for example, a film formed of p-type amorphous germanium may be included. A thickness of the second semiconductor film 13 is not particularly limited, and for example, is able to be greater than or equal to 1 nm and less than or equal to 20 nm. Here, as p-type impurities included in the second semiconductor film 13, for example, boron is able to be used, and a p-type impurity concentration of the second semiconductor film 13, for example, is able to be approximately 5×10¹⁹ units/cm³.

### (Third Semiconductor Film)

The third semiconductor film 5 is not particularly limited insofar as a film exhibits light transmittance, and as the third semiconductor film 5, for example, a known n-type amorphous semiconductor film of the related art, or the like may be used. A thickness of the third semiconductor film 5 is not particularly limited, and for example, is able to be greater than or equal to 1 nm and less than or equal to 20 nm. A n-type impurities included in the third semiconductor film 5, for example, phosphorus is able to be used, and an n-type impurity concentration of the third semiconductor film 5, for example, is able to be approximately 5×10¹⁹ units/cm³.

### <<Dielectric Film>>

In the present invention, the dielectric film is formed between the semiconductor substrate and each semiconductor film, is a film which passivates an interfacial surface between the semiconductor substrate and each of the semiconductor films without obstructing electric conduction between the semiconductor substrate and each of the semiconductor films. As such a dielectric film, an i-type non-doped film is preferable, and for example, a film formed of i-type amorphous silicon or the like is able to be preferably used. Hereinafter, each dielectric film will be described.

### (First Dielectric Film)

The first dielectric film 7 is formed between the semiconductor substrate 3 and the first semiconductor film 8. The first dielectric film 7 is not limited to a film formed of i-type amorphous silicon, and as the first dielectric film 7, for example, a known i-type amorphous semiconductor film of the related art, or the like may be used. A thickness of the first dielectric film 7 is not particularly limited, and for example, is able to be greater than or equal to 1 nm and less than or equal to 20 nm.

### (Second Dielectric Film)

The second dielectric film 12 is formed between the semiconductor substrate 3 and the second semiconductor film 13. The second dielectric film 12 is not limited to a film formed of i-type amorphous silicon, and as the second dielectric film 12, for example, a known i-type amorphous semiconductor film of the related art, or the like may be used. A thickness of the second dielectric film 12 is not particularly limited, and for example, is able to be greater than or equal to 1 nm and less than or equal to 20 nm.

### (Third Dielectric Film)

The third dielectric film 4 is formed between the semiconductor substrate 3 and the third semiconductor film 5. The third dielectric film 4 is not limited to a film formed of i-type amorphous silicon, and as the third dielectric film 4, for example, a known i-type amorphous semiconductor film of the related art, or the like may be used. A thickness of the third dielectric film 4 is not particularly limited, and for example, is able to be greater than or equal to 1 nm and less than or equal to 20 nm.

### <<Intermetallic Compound Layer>>

The intermetallic compound layer 15 of the present invention has a function of a p-type electrode or an n-type electrode. As the intermetallic compound layer 15, a layer exhibiting metallic electric conductivity is preferable, and a metal silicide layer and/or a metal germanide layer are more preferable.

Here, as metal silicide, for example, nickel silicide (NiSi), cobalt silicide (CoSi₂), titanium silicide (TiSi₂), molybdenum silicide (MoSi₂), palladium silicide (PdSi), platinum silicide (PtSi), manganese silicide (MnSi_{1.7}), tungsten silicide (WSi₂), and the like are able to be included. Then, among them, nickel silicide, cobalt silicide, titanium silicide, and a combination thereof are able to be preferably used. That is, it is preferable that the metal silicide layer of the present invention is a compound layer formed of silicon and at least one metal selected from a group consisting of nickel (Ni), cobalt (Co), and titanium (Ti).

In addition, as metal germanide, for example, nickel germanide (NiGe, NiGe₂), cobalt germanide (CoGe₂), titanium germanide (TiGe₂), molybdenum germanide (MoGe₂), palladium germanide, platinum germanide (PtGe), manganese germanide (Mn₅Ge₃), tungsten germanide (WGe₂), and the like are able to be included. Then, among them, nickel germanide, cobalt germanide, titanium germanide, and a combination thereof are able to be preferably used. That is, it is preferable that the metal germanide layer of the present invention is a compound layer formed of germanium and at least one metal selected from a group consisting of nickel (Ni), cobalt (Co), and titanium (Ti).

Furthermore, an intermetallic compound of the present invention may be a compound in which the compound described above is doped with a trace amount of other elements. In addition, in a composition thereof, each atom ratio follows the general expression described above. Furthermore, in the present invention, when the compound as described above is denoted by a chemical formula, all known atom ratios of the related art are included insofar as the atom ratio is not particularly limited, and are not necessarily limited only to a stoichiometric range. For example, when it is simply referred to as “NiSi”, an atom ratio of “Ni” to “Si” is not limited only to a case of 50:50, and all known atom ratios of the related art are included.

Further, the intermetallic compound layer 15 may be a single layer, or may be a laminated layer. In addition, the intermetallic compound layer 15 may include a silicon germanide layer.

In addition, a thickness of the intermetallic compound layer 15 is able to be greater than or equal to 0.1 μm and less than or equal to 1.0 μm, and more preferably is greater than or equal to 0.5 μm and less than or equal to 0.8 μm.

### <<Antireflective Film>>

As antireflective film 6, for example, a silicon oxide film, a silicon nitride film, and the like are able to be used, and a thickness of the antireflective film 6, for example, is able to be greater than or equal to 10 nm and less than or equal to 200 nm. When the thickness of the antireflective film 6 is less than 10 nm, an effect as an antireflective film may not be sufficiently obtained, and when the thickness exceeds 200 nm, it is difficult for solar light to transmit the antireflective film 6, and thus it is not preferable.

This photoelectric conversion element of this embodiment is manufactured by the following manufacturing method. In other words, the photoelectric conversion element manufactured by the following manufacturing method exhibits the properties described above. Therefore, the photoelectric conversion element of this embodiment is a photoelectric conversion element which is able to improve power generation efficiency and is able to be manufactured by a simple manufacturing process.

### [Manufacturing Method of Photoelectric Conversion Element]

Hereinafter, an example of a manufacturing method of the photoelectric conversion element 1 which is the first embodiment will be described with reference to schematic cross-sectional views of FIG. 3 to FIG. 17. Furthermore, the following examples are merely an example, and a sequence of a manipulation is not limited to the following examples, and is to be suitably changed.

First, as illustrated in FIG. 3, an alkali-tolerant resist film 9 including an opening portion 10 is formed on an opposite side (that is, the back surface) to a light receiving surface of the semiconductor substrate 3 formed of n-type single crystal silicon.

Here, the resist film 9 is not particularly limited, and as the resist film 9, for example, a film formed by printing alkali-tolerant resist ink in a portion other than a portion in which the opening portion 10 is formed using an ink jet method, and by drying the resist ink, or the like is able to be used.

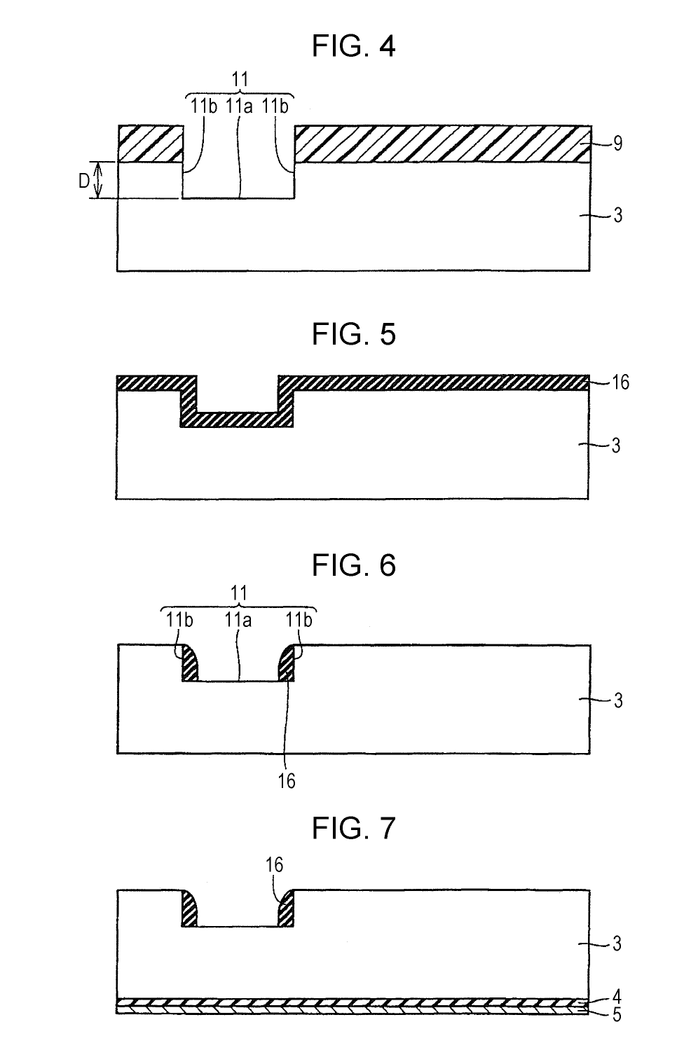

Next, as illustrated in FIG. 4, by removing a part of the back surface of the semiconductor substrate 3 which is exposed from the opening portion 10 of the resist film 9, the groove 11 formed of the bottom surface 11a, and the side walls 11b extending in the thickness direction of the semiconductor substrate 3 from both sides of the bottom surface 11a is formed. Here, it is preferable that anisotropic etching is first performed by dry etching, and then a damage layer which is generated by the dry etching is removed by wet etching.

Next, the resist film 9 is removed and cleaned, and then as illustrated in FIG. 5, the insulating film 16 is formed on the entire back surface of the semiconductor substrate 3 including the bottom surface 11a and the side walls 11b of the groove 11. A forming method of the insulating film 16 is not particularly limited, and any known method of the related art is able to be adopted.

When the insulating film 16 is a silicon oxide film, the insulating film 16 is able to be formed by steam oxidization, an ordinary pressure CVD method, or the like, and it is preferable that the insulating film 16 is formed by a thermal oxidization method. Here, it is preferable that a treatment temperature of the thermal oxidization method is 800° C. to 1100° C. The thermal oxidization method is a simple method, improves properties of the silicon oxide film to be formed compared to other manufacturing methods, is precise, and has a high passivation effect, and thus it is preferable. Here, a thickness of the insulating film 16 to be formed is able to be adjusted according to a treatment time, and for example, is able to be greater than or equal to 1 nm and less than or equal to 500 nm. In addition, after the thermal oxidation treatment, a hydrogen annealing treatment may be performed. Here, a treatment temperature of the hydrogen annealing treatment, for example, is able to be 300° C. to 500° C.

In addition, when the insulating film 16 is a silicon nitride film, the insulating film 16 is able to be formed by a vapor deposition method or the like, and it is preferable that the insulating film 16 is formed by a plasma CVD method. When the silicon nitride film is formed by a plasma CVD method, mixed gas formed of silane (SiH₄) gas and ammonia (NH₃) gas, or the like is able to be used as raw material gas. Here, a thickness of the insulating film 16 to be formed is able to be adjusted according to a film forming time, a film forming pressure, or the like, and for example, is able to be greater than or equal to 1 nm and less than or equal to 500 nm.

Next, as illustrated in FIG. 6, the insulating film 16 formed on a flat portion of the back surface of the semiconductor substrate 3 is removed. Thus, it is possible to obtain the semiconductor substrate 3 in which the insulating film 16 is formed on the side walls 11b of the groove 11. Here, a method of removing the insulating film 16 is not particularly limited, and as the method, either dry etching or wet etching may be used.

Next, as illustrated in FIG. 7, the third dielectric film 4 formed of i-type amorphous silicon and the third semiconductor film 5 formed of n-type amorphous silicon are laminated in this order on the entire light receiving surface of the semiconductor substrate 3 formed of n-type single crystal silicon, for example, by a plasma CVD method.

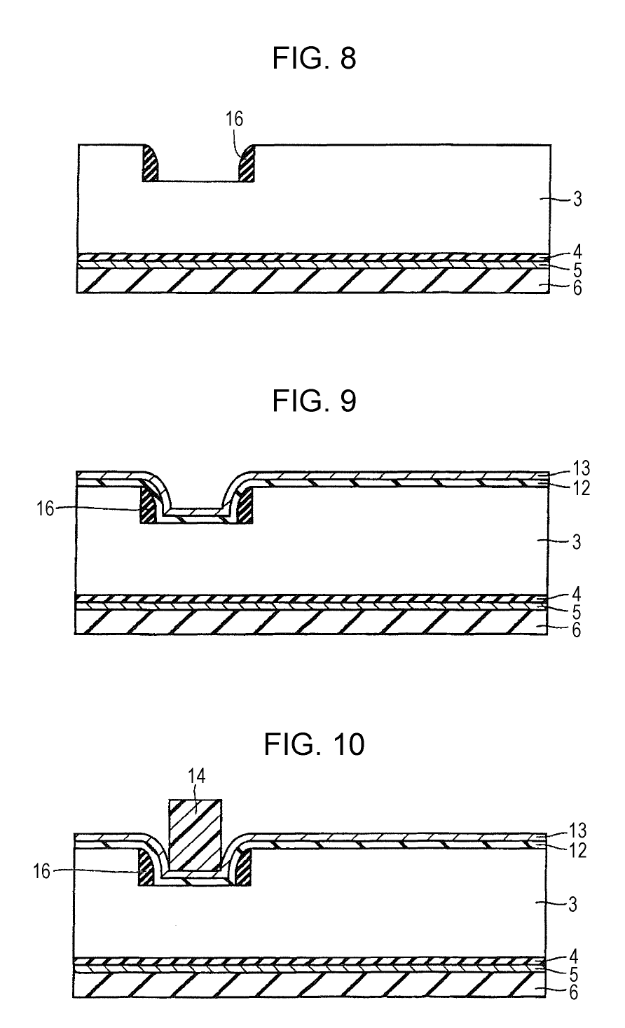

Next, as illustrated in FIG. 8, the antireflective film 6 is laminated on the entire surface of the third semiconductor film 5, for example, by a sputtering method, a CVD method, a vapor deposition method, or the like.

Next, as illustrated in FIG. 9, the second dielectric film 12 formed of i-type amorphous silicon and the second semiconductor film 13 formed of p-type amorphous silicon are laminated in this order on the entire back surface of the semiconductor substrate 3 including the insulating film 16 on the side walls 11b of the groove 11, for example, by a plasma CVD method. Here, in the second semiconductor film 13, a film formed of p-type amorphous silicon and a film formed of p-type amorphous germanium may be laminated, and in this case, the film formed of p-type amorphous germanium is laminated on the film formed of p-type amorphous silicon, for example, by a plasma CVD method.

Next, as illustrated in FIG. 10, a mask material 14 is embedded in at least a part of the groove 11. Here, the mask material 14 is able to be embedded in the groove 11, for example, by heating the mask material 14 to be in a melted state, by selectively applying the mask material 14 to be embedded in the groove 11 using an ink jet method, by cooling the mask material 14 to be in a solidified state, and then by drying the mask material 14.

Here, the mask material 14 is not particularly limited insofar as a material functions as an etching mask of the second dielectric film 12 and the second semiconductor film 13, and among them, it is preferable to use a hot melt adhesive agent. Furthermore, the hot melt adhesive agent is in a solid state at normal temperature, and is a melted state by heating, and thus has properties in which ooze of the hot melt adhesive agent after being applied decreases.

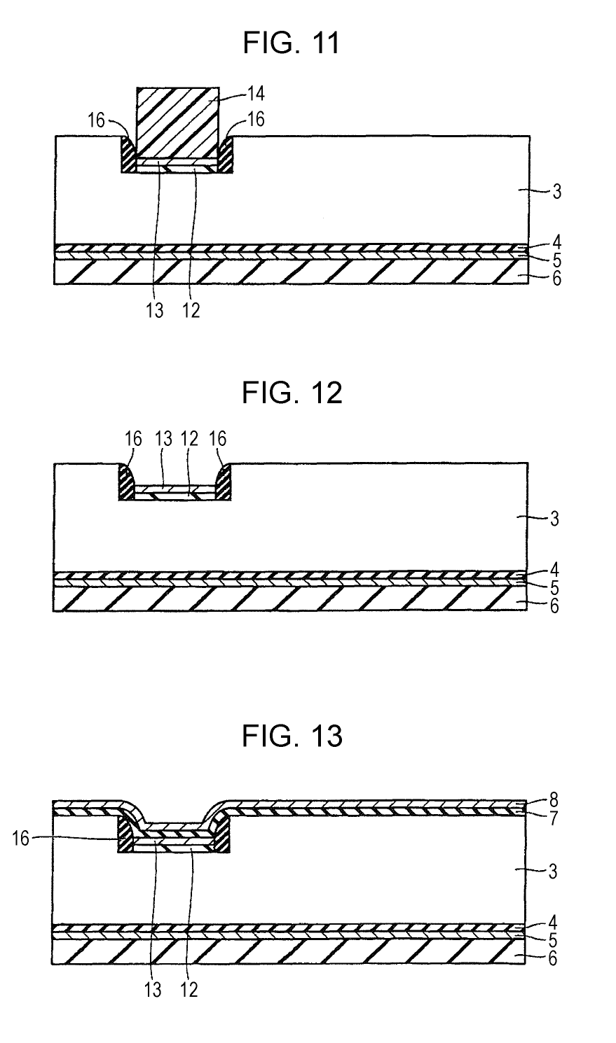

Next, as illustrated in FIG. 11, the second dielectric film 12 and the second semiconductor film 13 which are not covered with the mask material 14 are removed. Here, a method of removing the second dielectric film 12 and the second semiconductor film 13 is not particularly limited, and as the method, dry etching is preferably used.

Next, as illustrated in FIG. 12, the mask material 14 is removed, and then is cleaned. Here, a method of removing the mask material 14 is not particularly limited, and as the method, for example, when the mask material 14 is formed of a hot melt adhesive agent, a method in which the mask material 14 is immersed in hot water and is peeled off, or the like is included.

Next, as illustrated in FIG. 13, the first dielectric film 7 formed of i-type amorphous silicon and the first semiconductor film 8 formed of n-type amorphous silicon are laminated in this order on the entire back surface of the semiconductor substrate 3 after the mask material 14 is removed, for example, by a plasma CVD method. Here, in the first semiconductor film 8, a film formed of n-type amorphous silicon and a film formed of n-type amorphous germanium may be laminated, and in this case, the film formed of n-type amorphous germanium is laminated on the film formed of n-type amorphous silicon, for example, by a plasma CVD method.

Next, as illustrated in FIG. 14, a resist film 17 is formed in a portion of the back surface of the semiconductor substrate 3 other than the opening portion 10. Here, the resist film 17 is not particularly limited, and as the resist film 17, for example, the films exemplified above are able to be used.

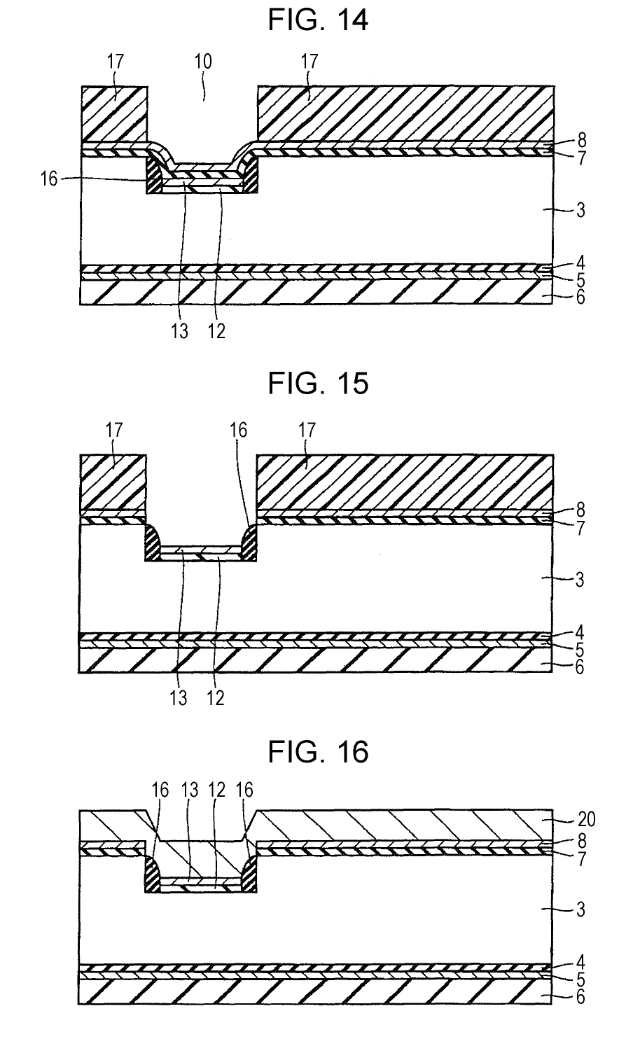

Next, as illustrated in FIG. 15, the first dielectric film 7 and the first semiconductor film 8 which are exposed from the opening portion 10 of the resist film 17 are removed, and the second semiconductor film 13 formed in the groove 11 is exposed. Here, as a method of removing the first dielectric film 7 and the first semiconductor film 8, wet etching using an alkali solution is preferably used. That is, it is difficult to remove the p-type second semiconductor film 13 by the wet etching using the alkali solution, and thus the second semiconductor film 13 functions as an etching stop layer, and the first dielectric film 7 and the first semiconductor film 8 are able to be reliably removed. Here, the alkali solution is not particularly limited, and as the alkali solution, for example, the solutions exemplified above are able to be used.

Next, the resist film 17 is removed, and then is cleaned. Next, as illustrated in FIG. 16, a metal layer 20 is formed on the entire surface on the back surface side of the semiconductor substrate 3. Here, the metal layer 20 is able to be formed by a known method of the related art, and for example, a CVD method, a sputtering method, a vapor deposition method, or the like is able to be preferably used. In addition, it is preferable that the metal layer 20 is formed of at least one metal selected from a group consisting of nickel (Ni), cobalt (Co), and titanium (Ti), and a thickness of the metal layer 20, for example, is able to be greater than or equal to 0.1 μm and less than or equal to 1.0 μm.

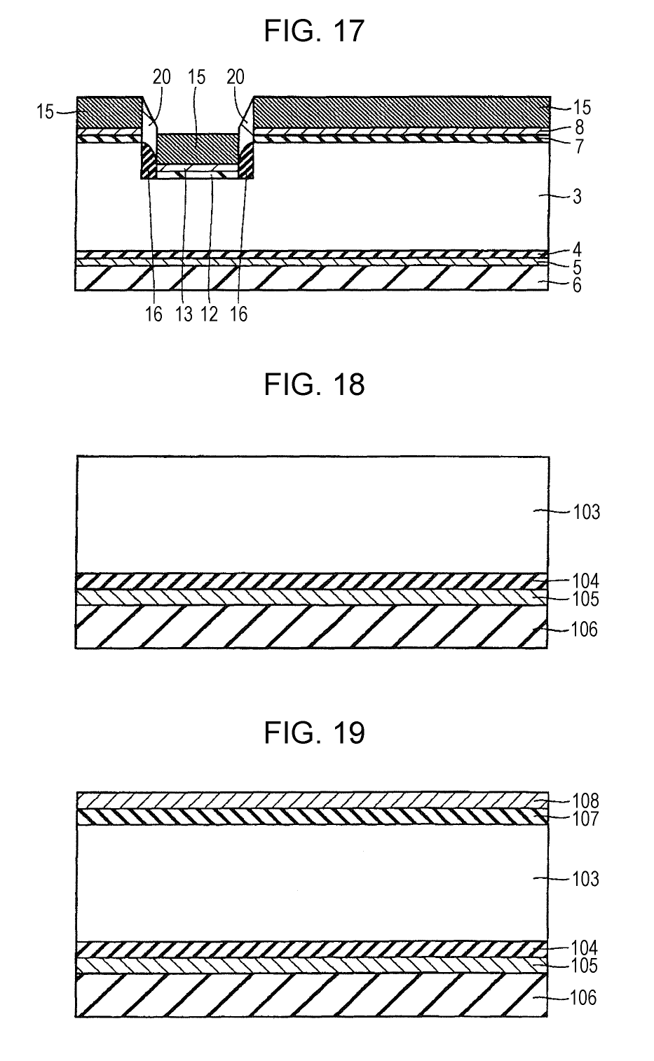

Next, as illustrated in FIG. 17, the metal layer 20 is formed, and then the metal layer 20 reacts with the first semiconductor film 8 and the second semiconductor film 13 by a heat treatment, and thus the intermetallic compound layer 15 is able to be formed. Here, when the intermetallic compound layer 15 is formed of a metal silicide layer, it is preferable that a heat treatment temperature is greater than or equal to 200° C. and less than or equal to 600° C.

Thus, when in the first semiconductor film 8 and the second semiconductor film 13, the film formed of amorphous germanium is laminated on the film formed of amorphous silicon, the intermetallic compound layer 15 is able to be a metal germanide layer. When the intermetallic compound layer 15 is the metal germanide layer, it is preferable that the heat treatment temperature is greater than or equal to 100° C. and less than or equal to 500° C. Thus, the metal germanide layer is able to be formed at a low temperature compared to a metal silicide layer, and thus it is preferable.

This is because when a groove is formed in a semiconductor substrate as in this embodiment, the semiconductor substrate may be curved or the like due to the groove (that is, a portion in which a thickness of the semiconductor substrate is different) when a heat treatment is performed at a high temperature exceeding 600° C. Therefore, in order to prevent such a problem from occurring, it is necessary that the temperature at which the metal layer and the semiconductor film reacts with each other is less than or equal to 600° C. The metal germanide layer is able to be formed at less than or equal to 500° C., and the problem such as the curving of the semiconductor substrate does not occur, and thus it is particularly preferable.

Furthermore, as illustrated in FIG. 17, the insulating film 16 and the metal layer 20 do not react with each other by the heat treatment, and thus the metal layer 20 on the insulating film 16 remains in an unreacted state.

Next, as illustrated in FIG. 1, the unreacted metal layer 20 is removed. Here, as a method of removing the unreacted metal layer 20, wet etching using an acidic solution is preferably used. The intermetallic compound layer 15 formed on the first semiconductor film 8 and the second semiconductor film 13 has corrosion resistance, and thus it is possible to selectively remove the unreacted metal layer 20 remaining on the insulating film 16 by using the acidic solution. By removing the unreacted metal layer 20, the intermetallic compound layer 15 on the first semiconductor film 8 and the intermetallic compound layer 15 on the second semiconductor film 13 are separated along the shape of the first semiconductor film 8 and the second semiconductor film 13 which are bases (that is, is separated in a self-matching manner). Accordingly, the intermetallic compound layer 15 is separated into the p-type electrode and the n-type electrode.

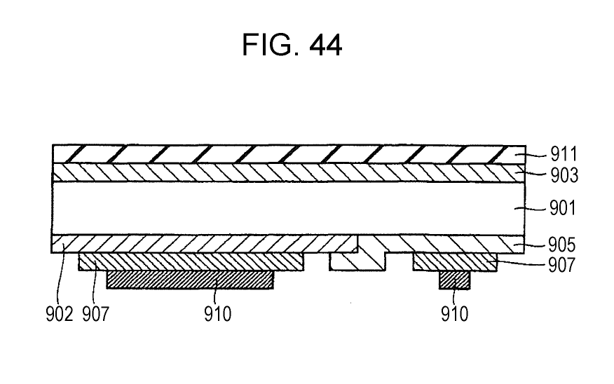

According to this embodiment, as the solar cell having the structure illustrated in FIG. 44, it is not necessary that the semiconductor film is coupled to the electrode layer by a transparent conductive oxide film, and thus contact resistance decreases, and it is possible to increase conversion efficiency of the photoelectric conversion element.

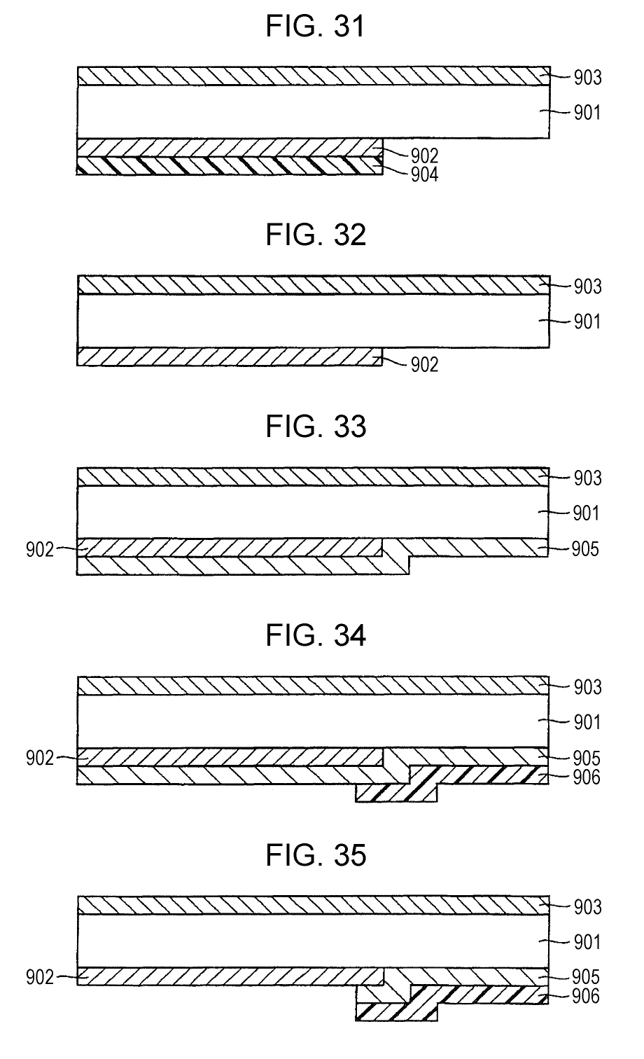

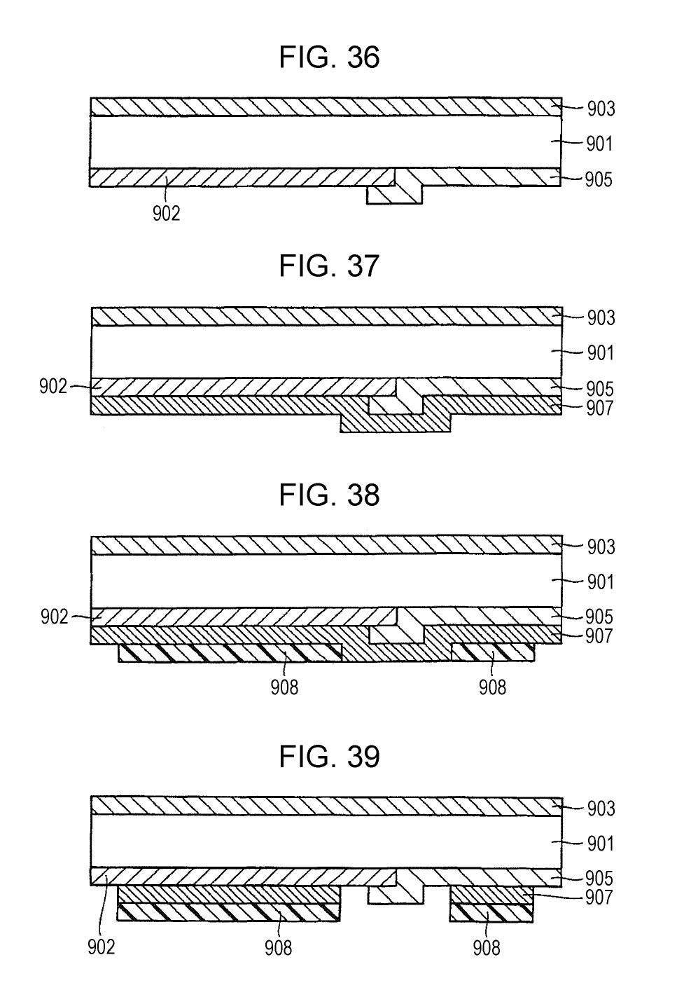

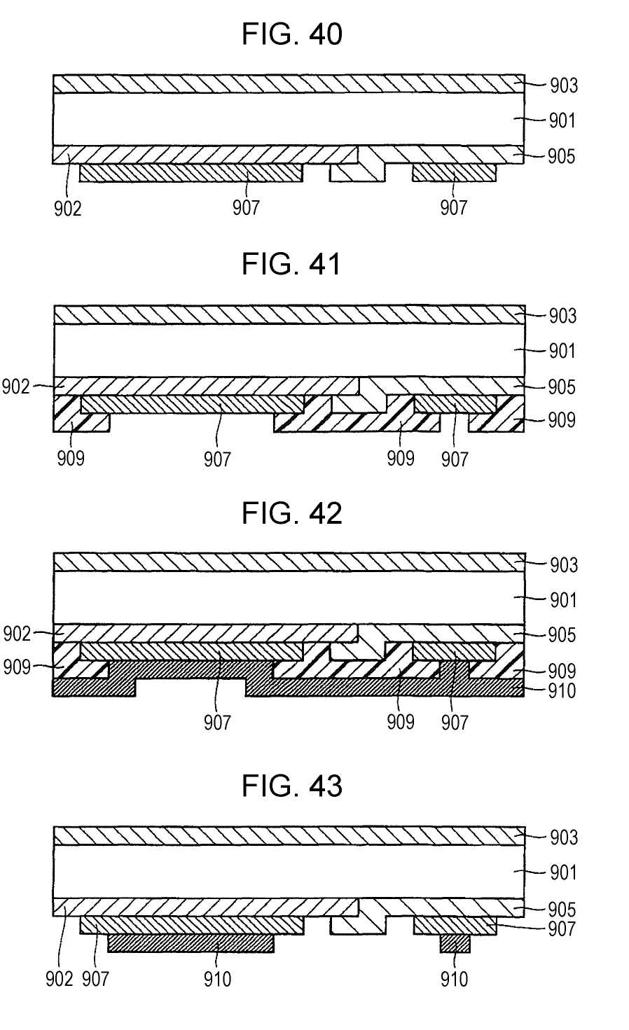

In addition, according to this embodiment, as the method illustrated in FIG. 28 to FIG. 44, it is not necessary to apply a photoresist, and to perform a complicated patterning process with respect to the photoresist by using a photolithography technology and an etching technology, and thus it is possible to manufacture the by a simpler manufacturing process.

In particular, as the method illustrated in FIGS. 37 to 44, it is not necessary to perform the complicated patterning process in forming the electrode, a low resistance electrode formed of the intermetallic compound layer is formed as described above, and it is possible to simply and reliably separate the p-type electrode (an electrode on the second semiconductor film 13) and the n-type electrode (an electrode on the first semiconductor film 8) from each other.

In addition, in this embodiment, the p-type electrode and the n-type electrode are formed in different positions in the thickness direction of the semiconductor substrate, and thus a gap between the p-type electrode and the n-type electrode on the back surface of the semiconductor substrate is able to be decreased, and it is not necessary to perform accurate patterning in order to form the p-type electrode and the n-type electrode having such a small gap. Here, it is difficult for a current to flow in a horizontal direction (a surface direction of a film) of an amorphous film (the first semiconductor film 8 and the second semiconductor film 13), and thus it is preferable that the gap between the p-type electrode and the n-type electrode on the back surface of the semiconductor substrate is as small as possible from a viewpoint of obtaining the photoelectric conversion element having high conversion efficiency. Then, in this embodiment, the p-type electrode and the n-type electrode are electrically separated from each other by the groove formed in the back surface and the insulating film formed on the side walls of the groove as described above, and thus a decrease in conversion efficiency which occurs when electric separation is not sufficient is prevented.

Further, in this embodiment, an entire flat surface of the back surface of the semiconductor substrate is able to be covered with the p-type electrode and the n-type electrode, and thus it is possible to reflect light transmitting the back surface side of the semiconductor substrate without being absorbed in light which is incident from the light receiving surface side of the semiconductor substrate by the p-type electrode and the n-type electrode. In addition, it is possible to reflect light transmitting the side wall of the groove by the insulating film formed on the side wall of the groove.

Further, in this embodiment, the entire flat surface of the back surface of the semiconductor substrate including the bottom surface of the groove of the semiconductor substrate is passivated by the i-type dielectric film, the n-type semiconductor film, and the p-type semiconductor film, and a part of the bottom surface of the groove and the side wall are also passivated by the insulating film. Therefore, excellent passivation properties are able to be obtained in the entire back surface of the semiconductor substrate, and it is possible to suppress a carrier recombination in the front surface of the semiconductor substrate.

According to the reasons described above, in this embodiment, it is possible to obtain the photoelectric conversion element having conversion efficiency which is higher than that of the solar cell having the structure illustrated in FIG. 44. In addition, in this embodiment, it is possible to manufacture the photoelectric conversion element having high conversion efficiency by a simple manufacturing process.

### Embodiment 2

### [Photoelectric Conversion Element]

### <<Overall Configuration>>

In FIG. 2, a schematic cross-sectional view of a photoelectric conversion element 2 which is a second embodiment of the present invention is illustrated. In the photoelectric conversion element 2, a first dielectric film 107 and a second dielectric film 112 which are formed of i-type amorphous silicon are disposed on a surface of a back surface of a semiconductor substrate 103 to be separated from each other without including a groove in the back surface of the semiconductor substrate 103. In addition, a first semiconductor film 108 formed of n-type amorphous silicon is disposed on the first dielectric film 107. In addition, a second semiconductor film 113 formed of p-type amorphous silicon is disposed on the second dielectric film 112. Then, an intermetallic compound layer 115 is disposed on entire back surfaces of the first semiconductor film 108 and the second semiconductor film 113.

In addition, an insulating film 116 is disposed between the first dielectric film 107 and the second dielectric film 112. Here, the insulating film 116 is formed in contact with side surface portions of the first dielectric film 107 and/or side surface portions of the second dielectric film 112. In addition, the insulating film 116 may be in contact with side surface portions of the first semiconductor film 108 and/or side surface portions of the second semiconductor film 113.

Similar to the photoelectric conversion element 1, a third dielectric film 104, a third semiconductor film 105, and an antireflective film 106 are disposed on a light receiving surface (a surface on an opposite side of the back surface) of the photoelectric conversion element 2. Here, as a semiconductor substrate, each film, a material and a thickness of each layer configuring the photoelectric conversion element 2, for example, the exemplifications described in the photoelectric conversion element 1 are able to be used.

Furthermore, in the photoelectric conversion element 2, a configuration in which the first semiconductor film 108 is n-type and the second semiconductor film 113 is p-type is exemplified, and even when the first semiconductor film p-type and the second semiconductor film is n-type, the effects of the present invention are obtained.

In addition, in the photoelectric conversion element 1, a configuration in which the third semiconductor film 105 is disposed on the light receiving surface is exemplified, but the third semiconductor film 105 is not a mandatory component, and even when the third semiconductor film 105 is not included, the effects of the present invention are obtained.

Such a photoelectric conversion element of this embodiment is manufactured by the following manufacturing method. In other words, the photoelectric conversion element manufactured by the following manufacturing method exhibits the properties described above. Therefore, the photoelectric conversion element of this embodiment is a photoelectric conversion element which is able to improve power generation efficiency and is able to be manufactured by a simple manufacturing process.

### [Manufacturing Method of Photoelectric Conversion Element]

Hereinafter, an example of a manufacturing method of the photoelectric conversion element 2 which is the second embodiment will be described with reference to schematic cross-sectional views of FIG. 18 to FIG. 27. Furthermore, the following examples are merely an example, and a sequence of a manipulation is not limited to the following examples, and is to be suitably changed.

First, as illustrated in FIG. 18, the third dielectric film 104 formed of i-type amorphous silicon and the third semiconductor film 105 formed of n-type amorphous silicon, and the antireflective film 106 are laminated in this order on the entire light receiving surface of the semiconductor substrate 103 formed of n-type single crystal silicon, for example, by a plasma CVD method.

Next, as illustrated in FIG. 19, the first dielectric film 107 formed of i-type amorphous silicon and the first semiconductor film 108 formed of n-type amorphous silicon are laminated in this order on the entire back surface of the semiconductor substrate 1 on the semiconductor substrate 103, for example, by a plasma CVD method. Here, in the first semiconductor film 108, a film formed of n-type amorphous silicon and a film formed of n-type amorphous germanium may be laminated, and in this case, the film formed of n-type amorphous germanium is laminated on the film formed of n-type amorphous silicon, for example, by a plasma CVD method.

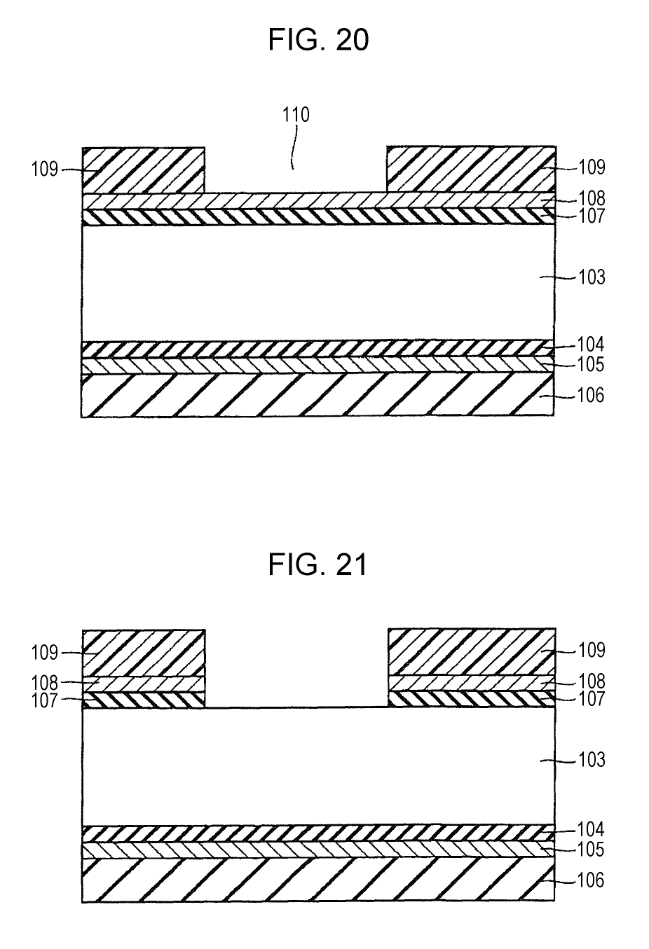

Next, as illustrated in FIG. 20, a resist film 109 including an opening portion 110 is formed. Here, the resist film 109 is not particularly limited, and as the resist film 109, for example, the exemplifications of the alkali-tolerant resist film described above are able to be used.

Next, as illustrated in FIG. 21, a part of the first dielectric film 107 and the first dielectric film 108 which is not covered with the resist film 109 is removed, and the semiconductor substrate 103 is exposed. Here, a method of removing the first dielectric film 107 and the first semiconductor film 108 is not particularly limited, and wet etching using an alkali solution is preferably used.

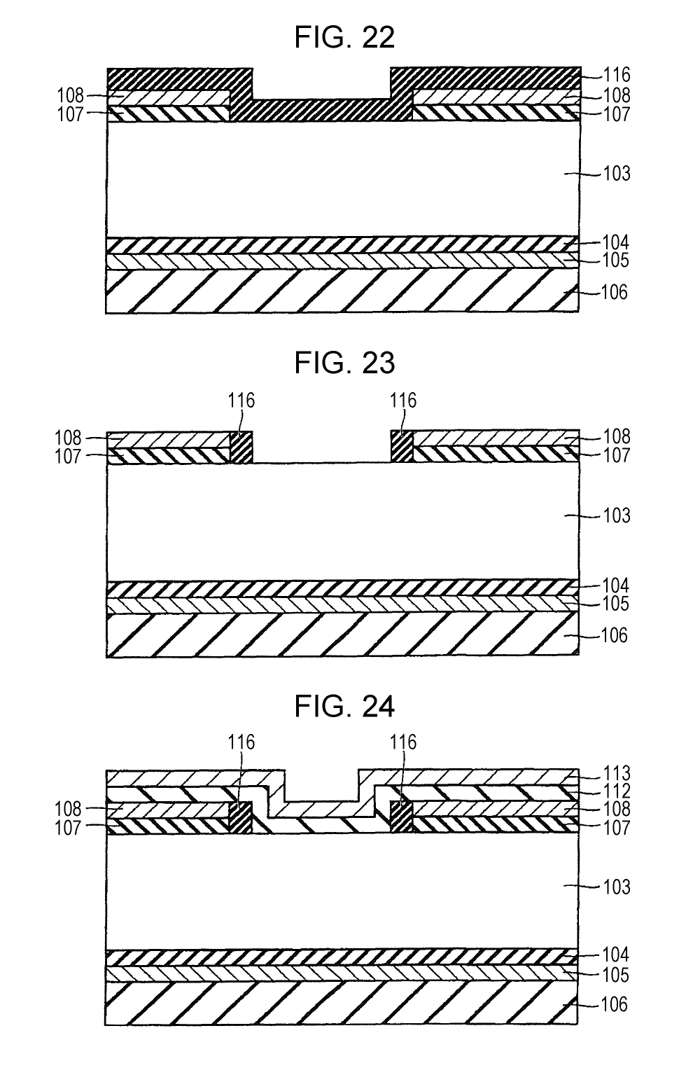

Next, the resist film 109 is removed and cleaned, and then, as illustrated in FIG. 22, the insulating film 116 is formed on an entire back surface of the first semiconductor film 108 and on an entire back surface of the semiconductor substrate 103. Here, as a method of forming the insulating film 116, for example, the method exemplified above is able to be used. In addition, as the insulating film 116, a thermally oxidized silicon film, and a silicon nitride film are preferable.

Next, as illustrated in FIG. 23, by removing the insulating film 116 formed on the flat surface, the insulating film 116 remains in the side surface portion of the first dielectric film 107 and the first semiconductor film 108. A method of removing the insulating film 116 is not particularly limited, and as the method, either dry etching or wet etching may be used.

Next, as illustrated in FIG. 24, the second dielectric film 112 formed of i-type amorphous silicon and the second semiconductor film 113 formed of p-type amorphous silicon are laminated in this order on the entire back surface of the first semiconductor film 108, on the entire back surface of the semiconductor substrate 103, and on a remaining portion of the insulating film 116, for example, by a plasma CVD method. Here, in the second semiconductor film 113, a film formed of p-type amorphous silicon and a film formed of p-type amorphous germanium may be laminated, and in this case, the film formed of p-type amorphous germanium is laminated on the film formed of p-type amorphous silicon, for example, by a plasma CVD method.

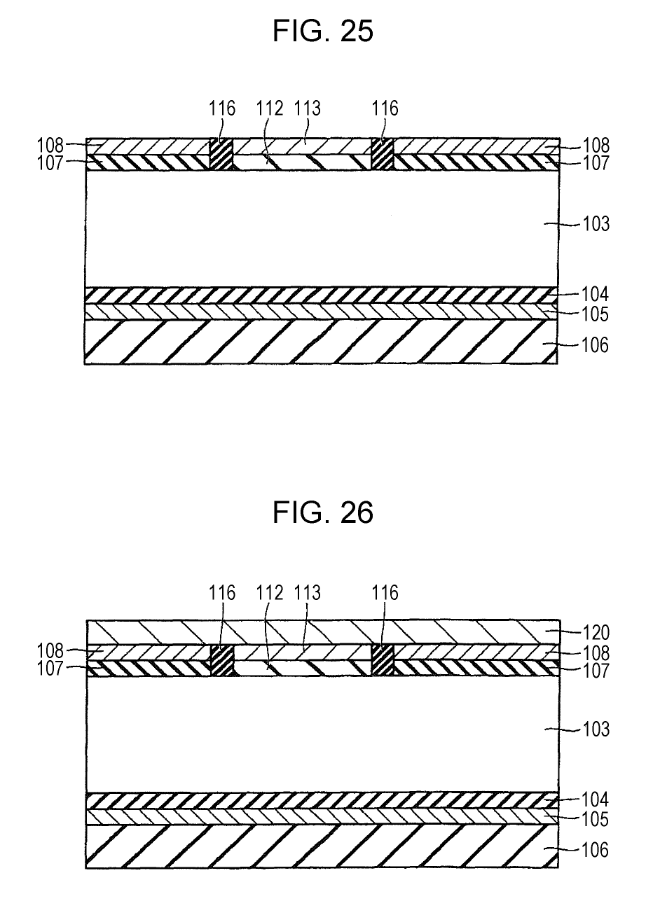

Next, as illustrated in FIG. 25, the second dielectric film 112 and the second semiconductor film 113 which are formed on the first semiconductor film 108 and on the remaining portion of the insulating film 116 are removed. Here, as a method of removing the second dielectric film 112 and the second semiconductor film 113, for example, the dry etching or the like exemplified above is able to be used.

Next, as illustrated in FIG. 26, a metal layer 120 is formed on the first semiconductor film 108, on the second semiconductor film 113, and on the remaining portion of the insulating film 116. Here, as a method of forming the metal layer 120, the sputtering method or the like exemplified above is able to be used, and it is preferable that the metal layer 120 is formed of at least one metal selected from a group consisting of nickel (Ni), cobalt (Co), and titanium (Ti).

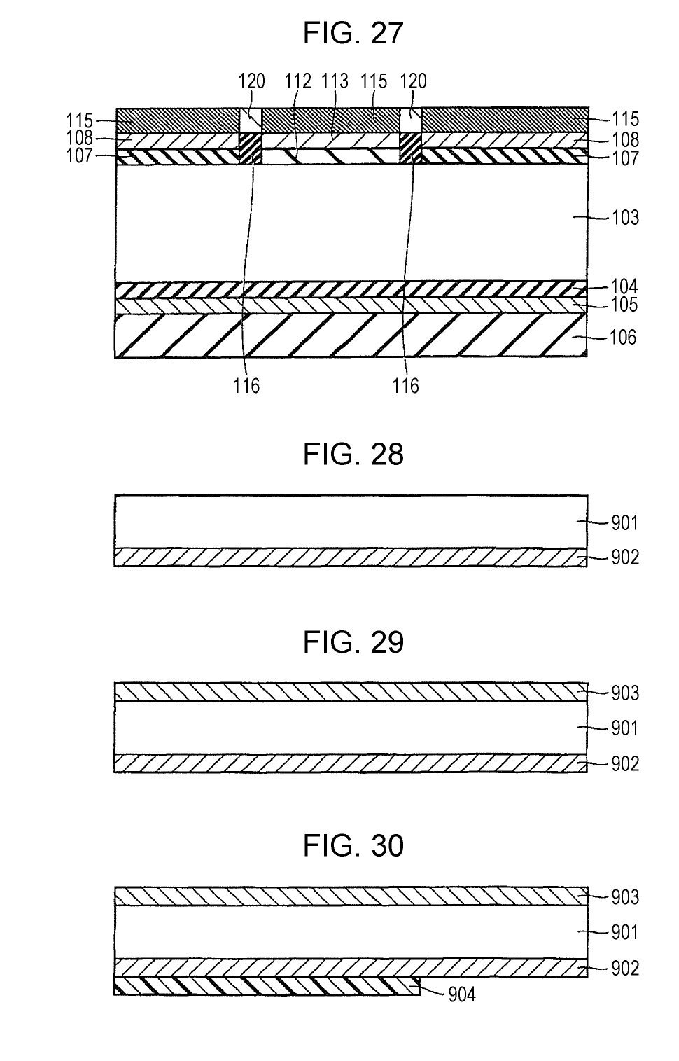

Next, as illustrated in FIG. 27, by performing a heat treatment, the metal layer 120 reacts with the first semiconductor film 108 and the second semiconductor film 113, and thus the intermetallic compound layer 115 is formed. Here, the insulating film 116 and the metal layer 120 do not react with each other by the heat treatment, and thus the metal layer 120 on the insulating film 116 remains in an unreacted state.

Next, as illustrated in FIG. 2, by removing the unreacted metal layer 120 on the on the insulating film 116, the intermetallic compound layer 115 is separated into a p-type electrode and an n-type electrode in a self-matching manner.

According to this embodiment, as the solar cell having the structure illustrated in FIG. 44, it is not necessary that the semiconductor film is coupled to the electrode layer by a transparent conductive oxide film, and thus contact resistance decreases, and it is possible to increase conversion efficiency of the photoelectric conversion element.

In addition, according to this embodiment, as the method illustrated in FIGS. 37 to 44, it is not necessary to perform a complicated patterning process in forming the electrode, a low resistance electrode formed of the intermetallic compound layer is formed as described above, and it is possible to simply and reliably separate the p-type electrode (an electrode on the second semiconductor film 113) and the n-type electrode (an electrode on the first semiconductor film 107) from each other.

Further, in this embodiment, an entire flat surface of the back surface of the semiconductor substrate is passivated by the i-type dielectric film, the n-type semiconductor film, the p-type semiconductor film, and the insulating film, and thus excellent passivation properties are able to be obtained in the entire back surface of the semiconductor substrate, and it is possible to suppress a carrier recombination in the front surface of the semiconductor substrate.

According to the reasons described above, in this embodiment, it is possible to obtain the photoelectric conversion element having conversion efficiency which is higher than that of the solar cell having the structure illustrated in FIG. 44. In addition, in this embodiment, it is possible to manufacture the photoelectric conversion element having high conversion efficiency by a simple manufacturing process.

As described above, the embodiments of the present invention are described, and the configuration of respective embodiments described above is originally planned to be suitably changed.

It is able to be considered that the embodiments disclosed herein are examples in all respects, and are not limited. It is intended that the range of the present invention is indicated by Claims, but not by the above description, and includes all changes in the meaning equivalent to Claims and the range.

### INDUSTRIAL APPLICABILITY

The present invention is able to be used in a photoelectric conversion element and a manufacturing method of a photoelectric conversion element.

### REFERENCE SIGNS LIST

1, 2 PHOTOELECTRIC CONVERSION ELEMENT
3, 103 SEMICONDUCTOR SUBSTRATE
4, 104 THIRD DIELECTRIC FILM
5, 105 THIRD SEMICONDUCTOR FILM
6, 106 ANTIREFLECTIVE FILM
7, 107 FIRST DIELECTRIC FILM
8, 108 FIRST SEMICONDUCTOR FILM
9, 17, 109 RESIST FILM
10, 110 OPENING PORTION
11 GROOVE
11A BOTTOM SURFACE
11B SIDE WALL
12, 112 SECOND DIELECTRIC FILM
13, 113 SECOND SEMICONDUCTOR FILM
14 MASK MATERIAL
15, 115 INTERMETALLIC COMPOUND LAYER
16, 116 INSULATING FILM
20, 120 METAL LAYER
901 c-Si (n) SUBSTRATE
902 a-Si (i/p) LAYER
903 a-Si (i/n) LAYER
904 PHOTORESIST FILM
905 a-Si (i/n) LAYER
906 PHOTORESIST FILM
907 TRANSPARENT CONDUCTIVE OXIDE FILM
908, 909 PHOTORESIST FILM
910 BACK SURFACE ELECTRODE LAYER
911 ANTIREFLECTIVE FILM

1. A photoelectric conversion element, comprising:
a semiconductor substrate of a first conductivity type;
a first semiconductor film of the first conductivity type disposed on one front surface of the semiconductor substrate;
a second semiconductor film of a second conductivity type disposed on the front surface to be independent from the first semiconductor film; and
a dielectric film disposed at least between the semiconductor substrate and the first semiconductor film or between the semiconductor substrate and the second semiconductor film,
wherein an intermetallic compound layer is formed on the first semiconductor film and on the second semiconductor film.

2. The photoelectric conversion element according to claim 1,
wherein a groove is formed in the front surface of the semiconductor substrate, and
the second semiconductor film is disposed on a bottom surface of the groove.

3. The photoelectric conversion element according to claim 1,
wherein the first semiconductor film and the second semiconductor film are disposed on the one front surface of the semiconductor substrate to be separated from each other, and
an insulating film is disposed between the first semiconductor film and the second semiconductor film.

4. The photoelectric conversion element according to claim 1,
wherein the intermetallic compound layer is at least any one of a metal silicide layer and a metal germanide layer.

5. The photoelectric conversion element according to claim 4,
wherein the metal germanide layer is a compound layer formed of germanium and at least one metal selected from a group consisting of nickel, cobalt, and titanium.
